(19) United States
(12) Patent Application Publication
(10) Pub. No.: US 2023/0375874 A1
(43) Pub. Date: Nov. 23, 2023

(54) LIQUID CRYSTAL OPTICAL ELEMENT

(71) Applicants: Japan Display Inc., Tokyo (JP); OSAKA UNIVERSITY, Osaka (JP)

(72) Inventors: Koichi IGETA, Tokyo (JP); Yasushi TOMIOKA, Tokyo (JP); Shinichiro OKA, Tokyo (JP); Hiroyuki YOSHIDA, Suita-shi (JP)

(73) Assignees: Japan Display Inc., Tokyo (JP); OSAKA UNIVERSITY, Osaka (JP)

(21) Appl. No.: 18/318,122

(22) Filed: May 16, 2023

(30) Foreign Application Priority Data
May 17, 2022 (JP) 2022-080911

(51) Int. Cl. G02F 1/1335; G02F 1/1337; G02F 1/13363

(52) U.S. Cl. CPC G02F 1/133543; G02F 1/133703; G02F 1/133636

(57) ABSTRACT

According to one embodiment, a liquid crystal optical element comprises a transparent substrate comprising a first main surface and a second main surface opposed to the first main surface, an alignment film disposed on the second main surface, and a liquid crystal layer overlapping the alignment film and comprising a cholesteric liquid crystal and an additive exhibiting a liquid crystalline property. Refractive anisotropy of the additive is greater than refractive anisotropy of the liquid crystal layer.

### CROSS-REFERENCE TO RELATED APPLICATIONS

This application is based upon and claims the benefit of priority from Japanese Patent Application No. 2022-080911, filed May 17, 2022, the entire contents of which are incorporated herein by reference.

### FIELD

Embodiments described herein relate generally to a liquid crystal optical element.

### BACKGROUND

For example, liquid crystal polarization gratings for which liquid crystal materials are used have been proposed. In such liquid crystal polarization gratings, it is necessary to adjust parameters such as the grating period, the refractive anisotropy Δn of a liquid crystal layer (difference between the refractive index ne for extraordinary light and the refractive index no for ordinary light of the liquid crystal layer), and the thickness d of the liquid crystal layer.

### BRIEF DESCRIPTION OF THE DRAWINGS

FIG. 1 is a cross-sectional view schematically showing a liquid crystal optical element 100 according to an embodiment.

FIG. 2 is a diagram for explaining an example of cholesteric liquid crystals 311 included in a liquid crystal layer 3.

FIG. 3 is a diagram for explaining another example of the cholesteric liquid crystals 311 included in the liquid crystal layer 3.

FIG. 4 is a plan view schematically showing the liquid crystal optical element 100.

FIG. 5 is a diagram showing material examples which can be applied as additive 4 in the embodiment.

FIG. 6 is a diagram showing material examples which can be applied as the additive 4 in the embodiment.

FIG. 7 is a diagram showing material examples which can be applied as the additive 4 in the embodiment.

FIG. 8 is a diagram showing material examples which can be applied as the additive 4 in the embodiment.

FIG. 9 is a diagram showing material examples which can be applied as the additive 4 in the embodiment.

FIG. 10 is a diagram showing material examples which can be applied as the additive 4 in the embodiment.

FIG. 11A is a diagram for explaining a manufacturing method of the liquid crystal optical element 100 according to the embodiment.

FIG. 11B is a diagram for explaining the manufacturing method of the liquid crystal optical element 100 according to the embodiment.

FIG. 11C is a diagram for explaining another manufacturing method of the liquid crystal optical element 100 according to the embodiment.

FIG. 12 is a diagram for explaining how the additive 4 penetrates.

FIG. 13 is a diagram showing measurement results of spectral transmission spectra of Samples 1 to 5.

FIG. 14 is a diagram showing the relationship between a selective reflection band Δλ and a center wavelength λm of Samples 1 to 5.

FIG. 15 is a diagram showing an example of the outside of a photovoltaic cell device 200.

FIG. 16 is a diagram for explaining the operation of the photovoltaic cell device 200.

### DETAILED DESCRIPTION

In general, according to one embodiment, a liquid crystal optical element comprises a transparent substrate comprising a first main surface and a second main surface opposed to the first main surface, an alignment film disposed on the second main surface, and a liquid crystal layer overlapping the alignment film and comprising a cholesteric liquid crystal and an additive exhibiting a liquid crystalline property. Refractive anisotropy of the additive is greater than refractive anisotropy of the liquid crystal layer.

According to another embodiment, a liquid crystal optical element comprises a transparent substrate comprising a first main surface and a second main surface opposed to the first main surface, an alignment film disposed on the second main surface, and a liquid crystal layer overlapping the alignment film and comprising a cholesteric liquid crystal and an additive exhibiting a liquid crystalline property. Refractive anisotropy of the additive is greater than refractive anisotropy of the cholesteric liquid crystal.

Embodiments will be described hereinafter with reference to the accompanying drawings. The disclosure is merely an example, and proper changes within the spirit of the invention, which are easily conceivable by a skilled person, are included in the scope of the invention as a matter of course. In addition, in some cases, in order to make the description clearer, the widths, thicknesses, shapes, etc., of the respective parts are schematically illustrated in the drawings, compared to the actual modes. However, the schematic illustration is merely an example, and adds no restrictions to the interpretation of the invention. Besides, in the specification and drawings, the same or similar elements as or to those described in connection with preceding drawings or those exhibiting similar functions are denoted by like reference numerals, and a detailed description thereof is omitted unless otherwise necessary.

In the drawings, an X-axis, a Y-axis, and a Z-axis orthogonal to each other are described to facilitate understanding as necessary. A direction along the Z-axis is referred to as a Z direction or a first direction A1, a direction along the Y-axis is referred to as a Y direction or a second direction A2, and a direction along the X-axis is referred to as an X direction or a third direction A3. A plane defined by the X-axis and the Y-axis is referred to as an X-Y plane, a plane defined by the X-axis and the Z-axis is referred to as an X-Z plane, and a plane defined by the Y-axis and the Z-axis is referred to as a Y-Z plane.

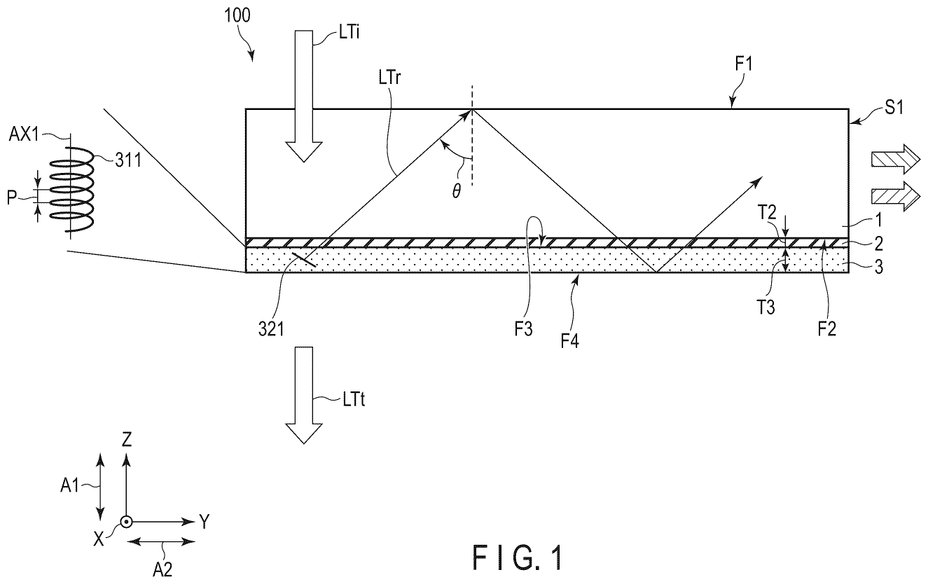

FIG. 1 is a cross-sectional view schematically showing a liquid crystal optical element 100 according to a present embodiment.

The liquid crystal optical element 100 comprises a transparent substrate 1, an alignment film 2, and a liquid crystal layer 3.

The transparent substrate 1 is composed of, for example, a transparent glass plate or a transparent synthetic resin plate. The transparent substrate 1 may be composed of, for example, a transparent synthetic resin plate having flexibility. The transparent substrate 1 can assume an arbitrary shape. For example, the transparent substrate 1 may be curved.

In the present specification, “light” includes visible light and invisible light. For example, the wavelength of the lower limit of the visible light range is greater than or equal to 360 nm but less than or equal to 400 nm, and the wavelength of the upper limit of the visible light range is greater than or equal to 760 nm but less than or equal to 830 nm. Visible light includes a first component (blue component) of a first wavelength band (for example, 400 nm to 500 nm), a second component (green component) of a second wavelength band (for example, 500 nm to 600 nm), and a third component (red component) of a third wavelength band (for example, 600 nm to 700 nm). Invisible light includes ultraviolet rays of a wavelength band shorter than the first wavelength band and infrared rays of a wavelength band longer than the third wavelength band.

In the present specification, to be “transparent” should preferably be to be colorless and transparent. Note that to be “transparent” may be to be translucent or to be colored and transparent.

The transparent substrate 1 is formed into the shape of a flat plate along the X-Y plane, and comprises a first main surface (outer surface) F1, a second main surface (inner surface) F2, and a side surface S1. The first main surface F1 and the second main surface F2 are surfaces substantially parallel to the X-Y plane and are opposed to each other in the first direction A1. The side surface S1 is a surface extending in the first direction A1. In the example shown in FIG. 1, the side surface S1 is a surface substantially parallel to the X-Z plane, but the side surface S1 includes a surface substantially parallel to the Y-Z plane.

The alignment film 2 is disposed on the second main surface F2. The alignment film 2 is a horizontal alignment film having alignment restriction force along the X-Y plane. The alignment film 2 is, for example, an optical alignment film for which alignment treatment can be performed by light irradiation, but may be an alignment film for which alignment treatment is performed by rubbing or may be an alignment film having minute irregularities. The thickness T2 in the first direction A1 of the alignment film 2 is 5 nm to 300 nm, preferably 10 nm to 200 nm.

The liquid crystal layer 3 overlaps the alignment film 2 in the first direction A1. That is, the alignment film 2 is located between the transparent substrate 1 and the liquid crystal layer 3, and is in contact with the transparent substrate 1 and the liquid crystal layer 3.

The liquid crystal layer 3 comprises a third main surface (inner surface) F3 and a fourth main surface (outer surface) F4. The third main surface F3 and the fourth main surface F4 are surfaces substantially parallel to the X-Y plane and are opposed to each other in the first direction A1. The third main surface F3 is in contact with the alignment film 2. The thickness T3 in the first direction A1 of the liquid crystal layer 3 is greater than the thickness T2, is for example, 1 μm to 10 μm, preferably 2 μm to 7 μm.

The fourth main surface F4 may be covered by a transparent protective layer.

As schematically shown in an enlarged manner, the liquid crystal layer 3 comprises a cholesteric liquid crystal 311 turning in a first turning direction. The cholesteric liquid crystal 311 has a helical axis AX1 substantially parallel to the first direction A1 and has a helical pitch P in the first direction A1. The helical pitch P indicates one cycle of the helix (layer thickness along the helical axis AX1 necessary for liquid crystal molecules to rotate 360 degrees).

The liquid crystal layer 3 comprises a reflective surface 321. The reflective surface 321 reflects circularly polarized light of a selective reflection band determined according to the helical pitch P of the cholesteric liquid crystal 311 and the refractive anisotropy Δn of the liquid crystal layer 3 of the light incident on the liquid crystal layer 3. For example, if the first turning direction is right-handed, right-handed circularly polarized light is reflected by the reflective surface 321, and if the first turning direction is left-handed, left-handed circularly polarized light is reflected by the reflective surface 321. In the present specification, “reflection” in the liquid crystal layer 3 involves diffraction inside the liquid crystal layer 3. In addition, in the present specification, circularly polarized light may be precise circularly polarized light or may be circularly polarized light approximate to elliptically polarized light.

In the example shown in FIG. 1, the liquid crystal layer 3 is configured to reflect part of light LTi incident from the first main surface F1 side toward the transparent substrate 1. The liquid crystal layer 3 also can be configured to reflect part of light incident from the fourth main surface F4 side. In addition, in the liquid crystal optical element 100, a liquid crystal layer comprising another cholesteric liquid crystal may be stacked on the liquid crystal layer 3 shown in FIG. 1. The other cholesteric liquid crystal is, for example, a cholesteric liquid crystal having a helical pitch different from the helical pitch P or a cholesteric liquid crystal turning in a second turning direction opposite to the first turning direction.

The optical action of the liquid crystal optical element 100 shown in FIG. 1 will be described next.

Light LTi incident on the liquid crystal optical element 100 includes, for example, visible light, ultraviolet rays, and infrared rays.

In the example shown in FIG. 1, to facilitate understanding, light LTi is incident substantially perpendicularly to the transparent substrate 1. The angle of incidence of light LTi to the transparent substrate 1 is not particularly limited. For example, light LTi may be incident on the transparent substrate 1 at angles of incidence different from each other.

Light LTi enters the inside of the transparent substrate 1 from the first main surface F1, is emitted from the second main surface F2, is transmitted through the alignment film 2, and is incident on the liquid crystal layer 3. Then, the liquid crystal layer 3 reflects part of light LTi. For example, the liquid crystal layer 3 reflects first circularly polarized light of infrared rays toward the transparent substrate 1 and transmits other light LTt.

The liquid crystal layer 3 reflects first circularly polarized light toward the transparent substrate 1 at an angle θ of entry which satisfies the conditions for optical waveguide in the transparent substrate 1. The angle θ of entry here corresponds to an angle greater than or equal to the critical angle θ_{C} which causes total reflection at the interface between the transparent substrate 1 and the air. The angle θ of entry indicates an angle to a perpendicular line orthogonal to the transparent substrate 1.

If the transparent substrate 1, the alignment film 2, and the liquid crystal layer 3 have equivalent refractive indices, the stacked layer body of these can be a single optical waveguide body. In this case, light LTr is guided toward the side surface S1 while being repeatedly reflected at the interface between the transparent substrate 1 and the air and the interface between the liquid crystal layer 3 and the air.

While the example in which infrared rays I are reflected has been explained here, the liquid crystal layer 3 may be configured to reflect visible light, or may be configured to reflect ultraviolet rays, or may be configured to reflect light of wavelength bands.

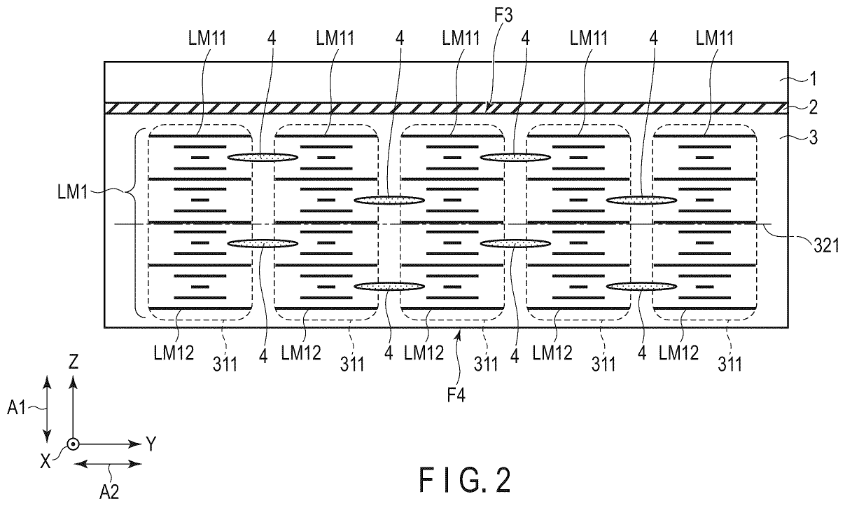

FIG. 2 is a diagram for explaining an example of cholesteric liquid crystals 311 included in the liquid crystal layer 3.

In FIG. 2, the liquid crystal layer 3 is shown in a state of being enlarged in the first direction A1. In addition, for the sake of simplification, one liquid crystal molecule LM1 of the liquid crystal molecules located in the same plane parallel to the X-Y plane is shown in the figure as liquid crystal molecules LM1 constituting the cholesteric liquid crystals 311. The alignment direction of the liquid crystal molecule LM1 shown in the figure corresponds to the average alignment direction of the liquid crystal molecules located in the same plane.

The liquid crystal layer 3 comprises the cholesteric liquid crystals 311 and additive (guest liquid crystal) 4 exhibiting liquid crystalline properties.

Each cholesteric liquid crystal 311 is constituted of liquid crystal molecules LM1 helically stacked in the first direction A1 while being turned. The liquid crystal molecules LM1 comprise a liquid crystal molecule LM11 on one end side of the cholesteric liquid crystals 311 and a liquid crystal molecule LM12 on the other end side of the cholesteric liquid crystals 311. The liquid crystal molecule LM11 is close to the third main surface F3 or the alignment film 2. The liquid crystal molecule LM12 is close to the fourth main surface F4.

In the liquid crystal layer 3 of the example shown in FIG. 2, the alignment directions of the cholesteric liquid crystals 311 adjacent to each other in the second direction A2 are the same. That is, the alignment directions of the liquid crystal molecules LM11 adjacent to each other in the second direction A2 are substantially identical. In addition, the alignment directions of the liquid crystal molecules LM12 adjacent to each other in the second direction A2 are also substantially identical.

The reflective surface 321 of the liquid crystal layer 3 is formed into the shape of a plane extending along the X-Y plane. The reflective surface 321 here corresponds to a surface along which the alignment directions of the liquid crystal molecules LM1 are the same or a surface along which spatial phases are the same (equiphase wave surface).

The above-described liquid crystal layer 3 is cured in a state where the alignment directions of the liquid crystal molecules LM1 are fixed. That is, the alignment directions of the liquid crystal molecules LM1 are not controlled in accordance with an electric field. For this reason, the liquid crystal optical element 100 does not comprise an electrode for forming an electric field in the liquid crystal layer 3.

The additive 4 penetrates the liquid crystal layer 3 substantially uniformly. The additive 4 is aligned in the same manner as the cholesteric liquid crystals 311. The additive 4 has refractive anisotropy Δn4. The refractive anisotropy Δn4 is greater than the refractive anisotropy Δn3 of the cholesteric liquid crystals 311. For this reason, the refractive anisotropy Δn of the liquid crystal layer 3 increases by the amount of additive 4 added to the liquid crystal layer 3. The refractive anisotropy Δn never exceeds the refractive anisotropy Δn4. That is, the refractive anisotropy Δn4 is greater than the refractive anisotropy Δn.

In general, in the liquid crystal layer 3 comprising the cholesteric liquid crystals 311, the selective reflection band Δλ for perpendicularly incident light is expressed as equation (1) below, based on the helical pitch P of the cholesteric liquid crystals 311 and the refractive anisotropy Δn of the liquid crystal layer 3 (difference between the refractive index ne for extraordinary light and the refractive index no for ordinary light).

Δλ=Δn*P (1)

The specific wavelength range of the selective reflection band Δλ is no*P to ne*P, and is for example, a near-infrared range of 800 nm to 1000 nm.

The center wavelength λm of the selective reflection band Δλ is expressed as equation (2) below, based on the helical pitch P of the cholesteric liquid crystals 311 and the average refractive index nav (=(ne+no)/2) of the liquid crystal layer 3.

Δm=nav*P (2)

According to the above equation (1), in order to meet a request to enlarge the selective reflection band Δλ, the refractive anisotropy Δn or the helical pitch P needs to be increased. However, as indicated by the above equation (2), the helical pitch P affects the center wavelength λm as well. For this reason, in order to enlarge the selective reflection band Δλ while suppressing the shift of the center wavelength λm to a long wavelength side, increasing the refractive anisotropy Δn is effective.

According to the present embodiment, the liquid crystal layer 3 comprises the additive 4 in addition to the cholesteric liquid crystals 311. The refractive anisotropy Δn4 of the additive 4 is greater than the refractive anisotropy Δn3 of the cholesteric liquid crystals 311. For this reason, the refractive anisotropy Δn of the liquid crystal layer 3 can be increased compared to that in a case where the liquid crystal layer 3 does not comprise the additive 4. It is therefore possible to enlarge the selective reflection band Δλ in the liquid crystal layer 3.

In addition, even if it is hard to select a material for achieving desired refractive anisotropy Δn as a material for forming the cholesteric liquid crystals 311, the desired refractive anisotropy Δn can be easily achieved by adjusting the amount of added additive 4.

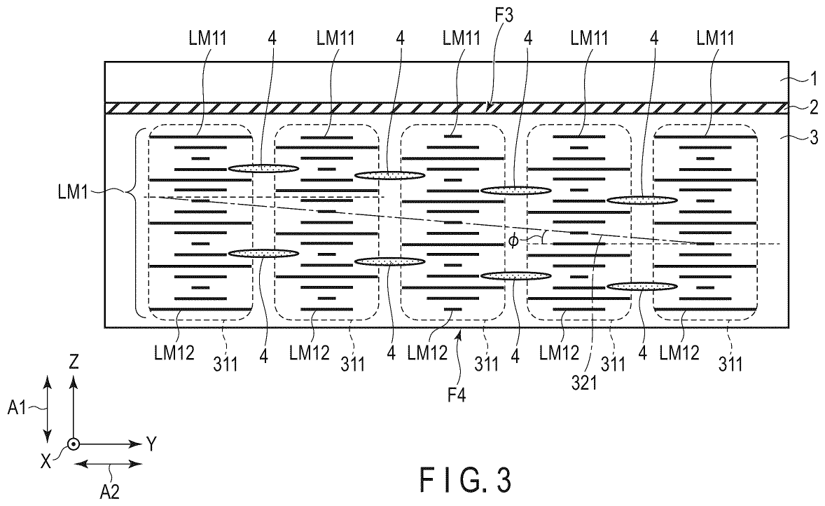

FIG. 3 is a diagram for explaining another example of the cholesteric liquid crystals 311 included in the liquid crystal layer 3.

The example shown in FIG. 3 is different from the example shown in FIG. 2 in that the alignment directions of the cholesteric liquid crystals 311 adjacent to each other in the second direction A2 are different from each other. In addition, the respective spatial phases of the cholesteric liquid crystals 311 adjacent to each other in the second direction A2 are different from each other. Moreover, the alignment directions of the liquid crystal molecules LM11 change continuously in the second direction A2. Furthermore, the alignment directions of the liquid crystal molecules LM12 also change continuously in the second direction A2. These alignment directions will be described later.

The reflective surface 321 of the liquid crystal layer 3 is inclined with respect to the X-Y plane. The angle φ formed by the reflective surface 321 and the X-Y plane is an acute angle.

The shape of the reflective surface 321 is not limited to a planar shape as shown in FIG. 2 and FIG. 3, but may be a curved surface such as a concave shape or a convex shape and is not particularly limited. In addition, part of the reflective surface 321 may have irregularities, or the angles φ of inclination of reflective surfaces 321 may not be uniform, or reflective surfaces 321 may not be arranged regularly. According to the spatial phase distribution of the cholesteric liquid crystals 311, the reflective surface 321 having an arbitrary shape can be formed.

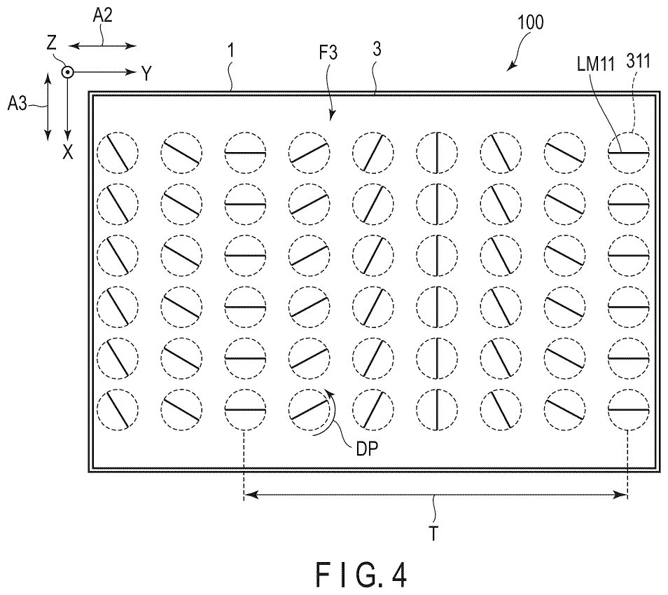

FIG. 4 is a plan view schematically showing the liquid crystal optical element 100.

FIG. 4 shows an example of the spatial phases of the cholesteric liquid crystals 311. The spatial phases here are shown as the alignment directions of the liquid crystal molecules LM11 located close to the third main surface F3 of the liquid crystal molecules LM1 included in the cholesteric liquid crystals 311.

The alignment directions of the liquid crystal molecules LM11 differ from each other between each cholesteric liquid crystal 311 arranged in the second direction A2. That is, the spatial phases of the cholesteric liquid crystals 311 are different in the second direction A2.

In contrast, the alignment directions of the liquid crystal molecules LM11 are substantially identical between each cholesteric liquid crystal 311 arranged in the third direction A3. That is, the spatial phases of the cholesteric liquid crystals 311 are substantially identical in the third direction A3.

In particular, in the cholesteric liquid crystals 311 arranged in the second direction A2, the respective alignment directions of the liquid crystal molecules LM11 differ by equal angles. That is, the alignment directions of the liquid crystal molecules LM11 arranged in the second direction A2 change linearly. Accordingly, the spatial phases of the cholesteric liquid crystals 311 arranged in the second direction A2 change linearly in the second direction A2. As a result, as in the liquid crystal layer 3 shown in FIG. 3, the reflective surface 321 inclined with respect to the X-Y plane is formed. The phrase “linearly change” here means, for example, that the amount of change of the alignment directions of the liquid crystal molecules LM11 is represented by a linear function. The alignment directions of the liquid crystal molecules LM11 here correspond to the major-axis directions of the liquid crystal molecules LM11 in the X-Y plane. The above-described alignment directions of the liquid crystal molecules LM11 are controlled by the alignment treatment performed for the alignment film 2.

Here, as shown in FIG. 4, in one plane, the interval between two liquid crystal molecules LM11 between which the alignment directions change by 180 degrees in the second direction A2 is defined as a cycle T. In FIG. 4, DP denotes the turning direction of the liquid crystal molecules LM11. The angle φ of inclination of the reflective surface 321 shown in FIG. 3 is set as appropriate by the cycle T and the helical pitch P.

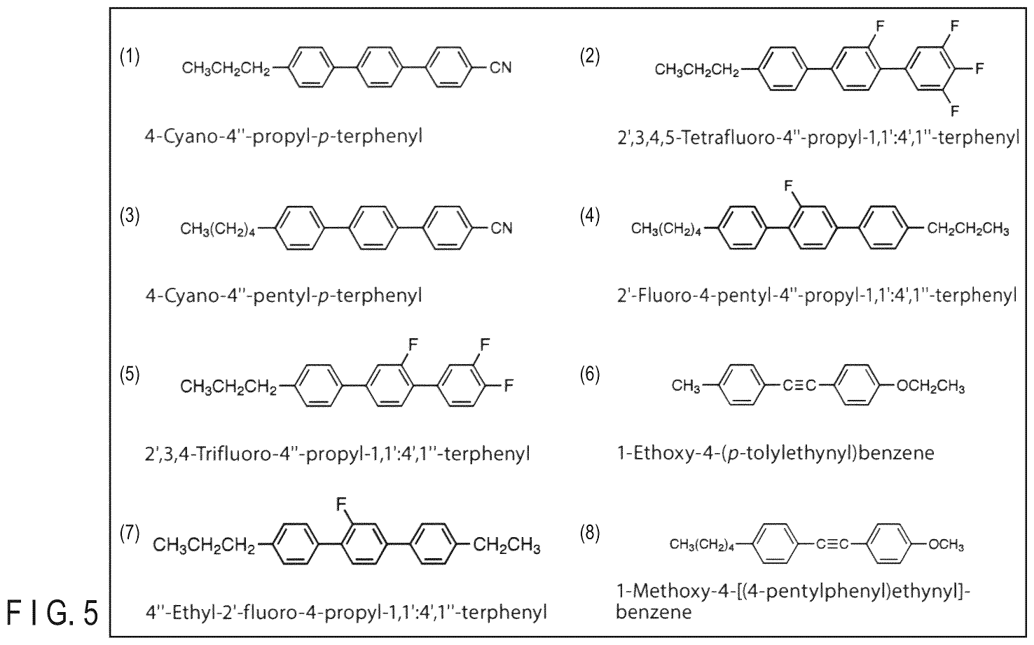

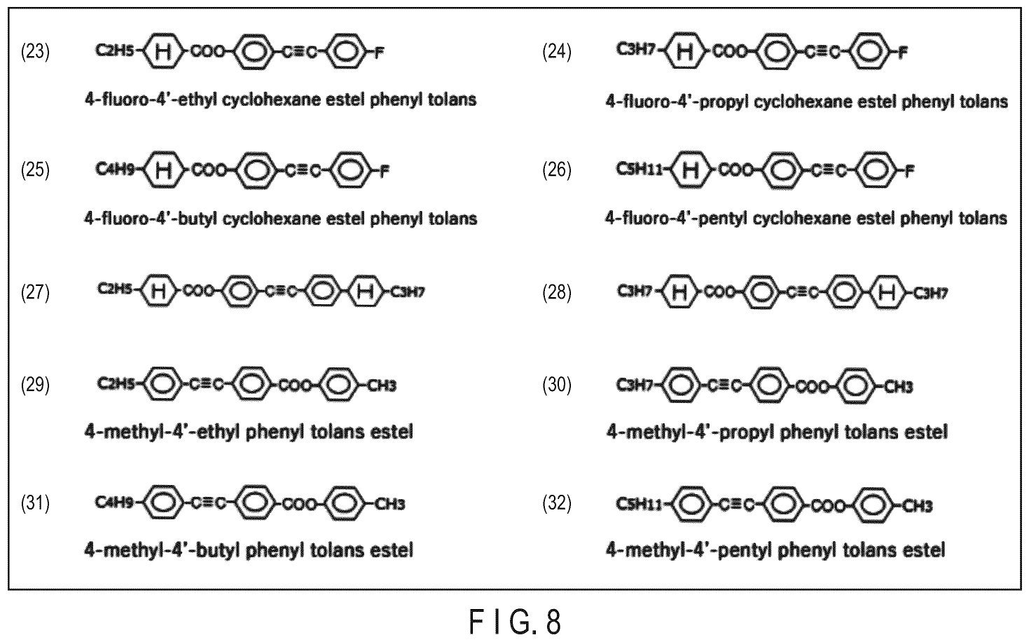

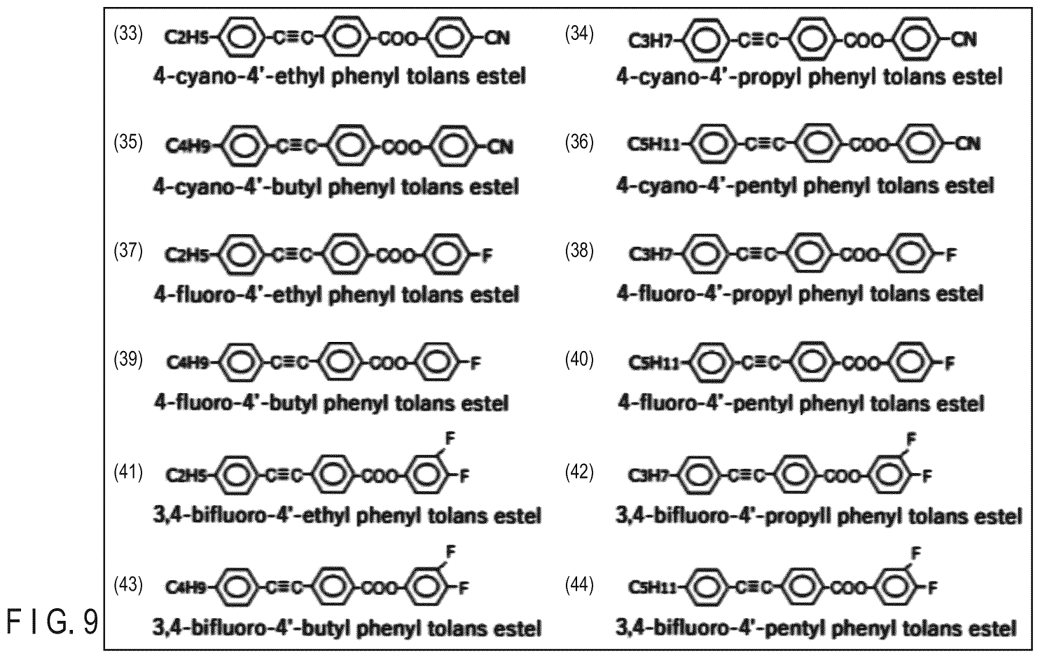

Material examples which can be applied as the above-described additive 4 will be described here with reference to FIG. 5 to FIG. 10.

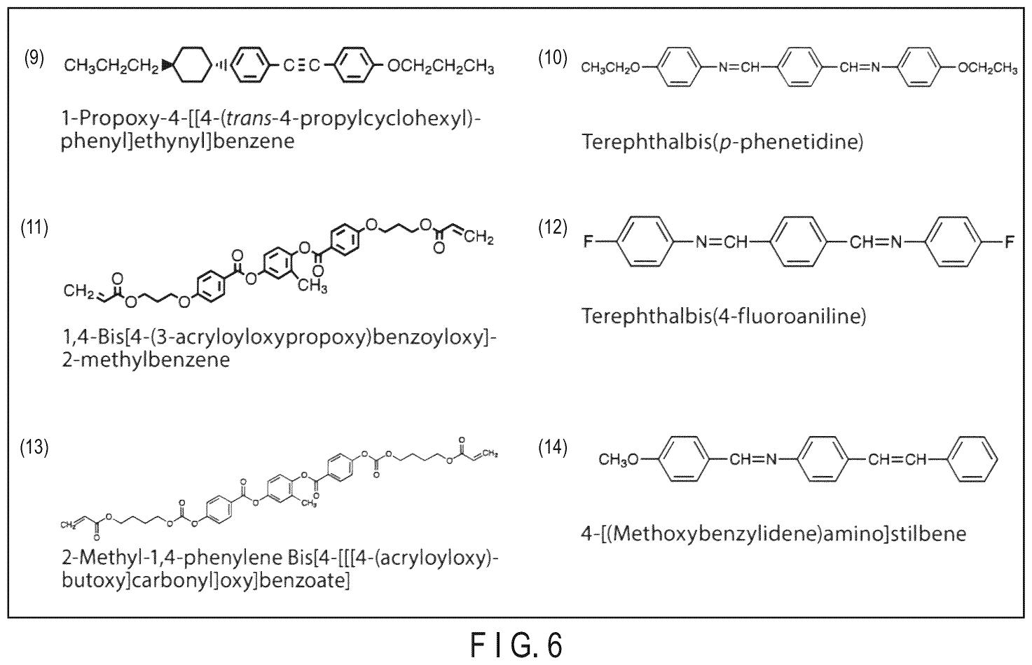

Material examples (1) to (8) shown in FIG. 5 and material examples (9) to (14) shown in FIG. 6 are examples of nematic liquid crystal materials and smectic liquid crystal materials, and are cyanobiphenyl-based materials and analogs thereof, fluorinated biphenyl-based materials and analogs thereof, other biphenyl-based materials and analogs thereof, phenyl ester-based materials, and Schiff base-based materials.

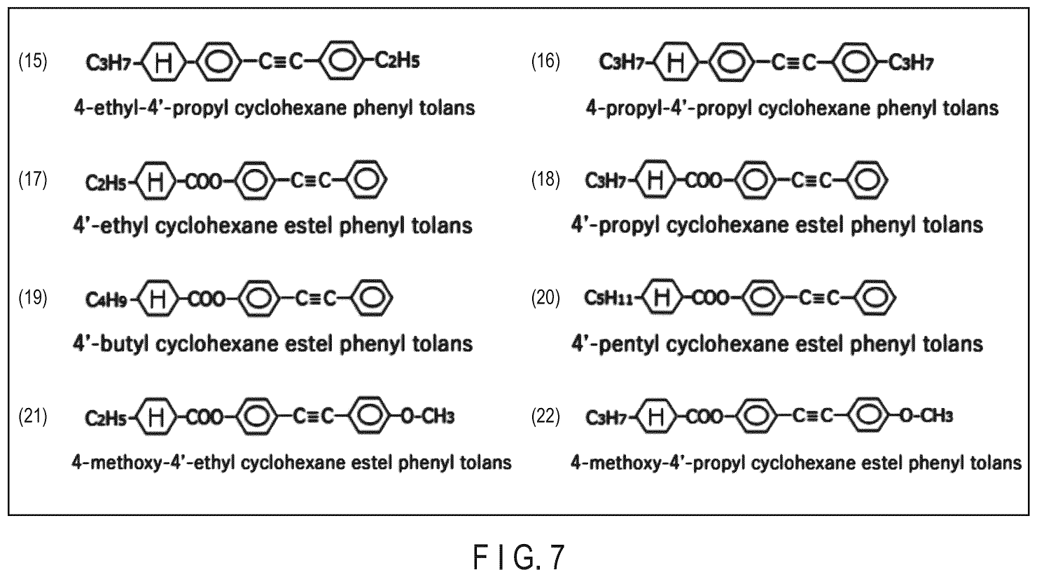

Material examples (15) to (44) shown in FIG. 7 to FIG. 9 are examples of nematic liquid crystal materials and smectic liquid crystal materials, and are tolan-based materials.

Material examples (15) and (16) are cyclohexane phenyl tolan-based materials.

Material examples (17) to (20) are cyclohexane ester phenyl tolan-based materials.

Material examples (21) and (22) are alkoxy cyclohexane ester phenyl tolan-based materials.

Material examples (23) to (26) are fluoro cyclohexane ester phenyl tolan-based materials.

Material examples (27) and (28) are tetracyclic ester tolan-based materials.

Material examples (29) to (32) are phenyl tolan ester-based materials.

Material examples (33) to (36) are cyano phenyl tolan ester-based materials.

Material examples (37) to (40) are fluoro phenyl tolan ester-based materials.

Material examples (41) to (44) are bifluoro phenyl tolan ester-based materials.

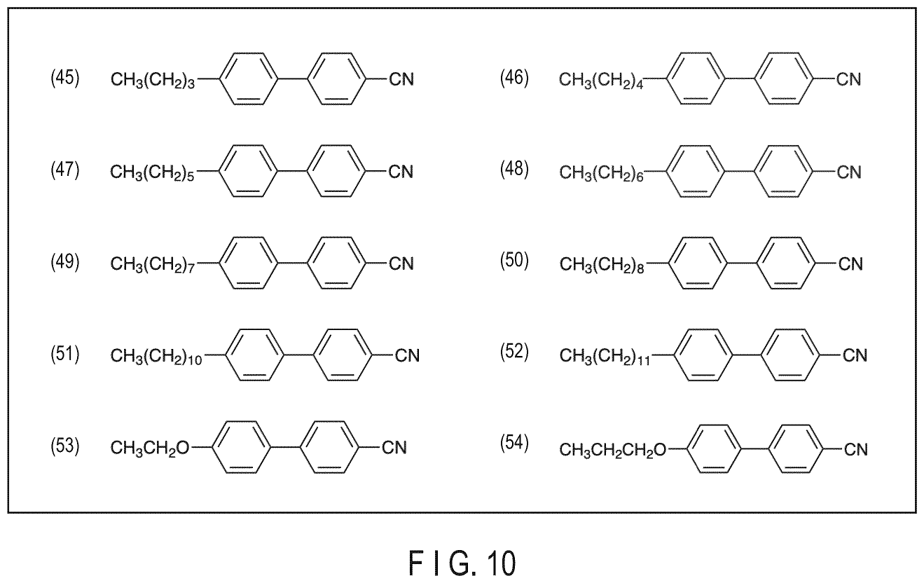

Material examples (45) to (54) shown in FIG. 10 are examples of nematic liquid crystal materials and smectic liquid crystal materials, and are cyano biphenyl-based materials and analogs thereof.

A manufacturing method of the liquid crystal optical element 100 will be described next.

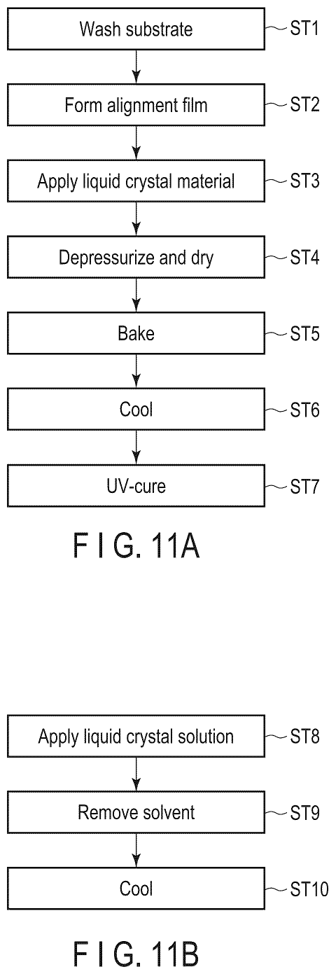

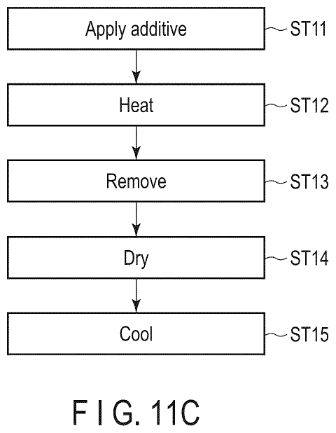

First, as shown in FIG. 11A, the transparent substrate 1 is washed (step ST1).

Then, the alignment film 2 is formed on the second main surface F2 of the transparent substrate 1 (step ST2). The alignment film 2 is subjected to predetermined alignment treatment.

Then, a liquid crystal material (solution including a monomeric material for forming cholesteric liquid crystals) is applied to the alignment film 2 (step ST3). Then, a solvent is dried by depressurizing the inside of a chamber (step ST4) to further bake the liquid crystal material (step ST5). Through the baking, the liquid crystal molecules included in the liquid crystal material are aligned in a predetermined direction in accordance with the direction of the alignment treatment of the alignment film 2. Then, the liquid crystal material is cooled to room temperature or so (step ST6), and after that, the liquid crystal material is irradiated with ultraviolet rays and the liquid crystal material is cured (step ST7). The liquid crystal layer 3 comprising the cholesteric liquid crystals 311 is thereby formed.

Next, as shown in FIG. 11B, a liquid crystal solution obtained by dissolving the above additive 4 in a solvent is prepared. As the solvent, organic solvents such as hexane, cyclohexane, cyclohexanone, heptane, toluene, anisole, propylene glycol monomethyl ether acetate (PGMEA) can be applied. Then, the liquid crystal solution is applied to the liquid crystal layer 3 (step ST8). The application here includes soaking the liquid crystal layer 3 in the liquid crystal solution and dropping the liquid crystal solution on the liquid crystal layer 3. The additive 4 included in the liquid crystal solution, together with the solvent, thereby penetrates the liquid crystal layer 3 uniformly. Of the applied liquid crystal solution, excess liquid crystal solution is removed by a spinner or the like. As necessary, an organic solvent for removing liquid crystal solution may be used.

Then, the solvent which has penetrated the liquid crystal layer 3, is removed by heating the transparent substrate 1 (step ST9). Then, the transparent substrate 1 is cooled to room temperature or so (step ST10).

The amount of additive 4 added to the liquid crystal layer 3 can be adjusted by the number of times the above-described steps ST8 to ST10 are carried out. That is, if it is required that the amount of added additive 4 be increased, steps ST8 to ST10 are carried out repeatedly more than once. In this way, the liquid crystal optical element 100 having desired reflective performance is manufactured.

Instead of the steps shown in FIG. 11B, the steps shown in FIG. 11C may be applied. The steps shown in FIG. 11C will be described hereinafter.

First, the additive 4 is prepared. Then, the additive 4 is applied to the liquid crystal layer 3 (step ST11). The application here includes soaking the liquid crystal layer 3 in the additive 4 and dropping the additive 4 on the liquid crystal layer 3.

Then, the transparent substrate 1 is heated to bring the applied additive 4 into a liquid state beyond a nematic-isotropic transition temperature (NI point) (step ST12).

The additive 4 thereby penetrates the liquid crystal layer 3 uniformly.

After that, excess additive 4 is removed by a spinner or the like (step ST13). As necessary, an organic solvent for removing excess additive 4 may be used.

Then, the liquid crystal layer 3 is dried by heating the transparent substrate 1 (step ST14).

Then, the transparent substrate 1 is cooled to room temperature or so (step ST15).

The amount of additive 4 added to the liquid crystal layer 3 can be adjusted by the number of times the above-described steps ST11 to ST15 are carried out. That is, if it is required that the amount of added additive 4 be increased, steps ST11 to ST15 are carried out repeatedly more than once. In this way, the liquid crystal optical element 100 having desired reflective performance is manufactured.

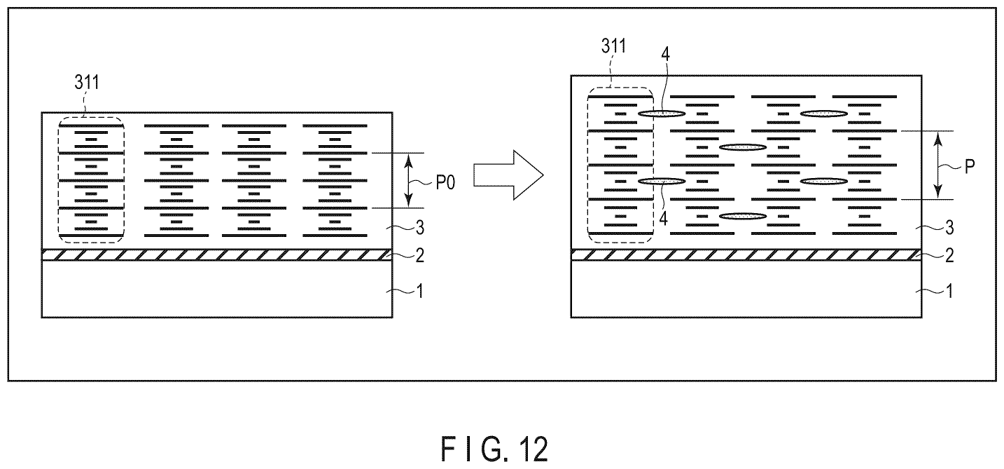

FIG. 12 is a diagram for explaining how the additive 4 penetrates. The left side of FIG. 12 shows the liquid crystal optical element 100 before the liquid crystal solution is applied, and the right side of FIG. 12 shows the liquid crystal optical element 100 after the liquid crystal solution is applied. FIG. 12 schematically shows how the additive 4 is added.

In the liquid crystal layer 3 before the liquid crystal solution is applied, the cholesteric liquid crystals 311 have a helical pitch P0.

The liquid crystal layer 3 after the liquid crystal solution is applied swells because of the penetration of the liquid crystal solution including the additive 4. For this reason, the helical pitch P of the cholesteric liquid crystals 311 becomes greater than the helical pitch P0.

### Example 1

First, a liquid crystal material having refractive anisotropy Δn3 of 0.2 was applied as a material for forming the cholesteric liquid crystals 311, and the liquid crystal layer 3 was formed through the above-described steps ST1 to ST7.

Then, a liquid crystal solution with a concentration of 10 wt % was prepared by dissolving 4-Cyano-4″-pentyl-p-terphenyl (another name: 5CT) as the additive 4 in cyclohexanone as a solvent. Then, through the above-described steps ST8 to ST10, the additive 4 was added to the liquid crystal layer 3.

In this way, five samples were prepared.

Sample 1 did not include the additive 4.

Sample 2 was prepared by carrying out the above-described steps ST8 to ST10 once to add the additive 4.

Sample 3 was prepared by carrying out the above-described steps ST8 to ST10 twice to add the additive 4.

Sample 4 was prepared by carrying out the above-described steps ST8 to ST10 three times to add the additive 4.

Sample 5 was prepared by carrying out the above-described steps ST8 to ST10 four times to add the additive 4.

The spectral transmission spectra of these five samples were measured.

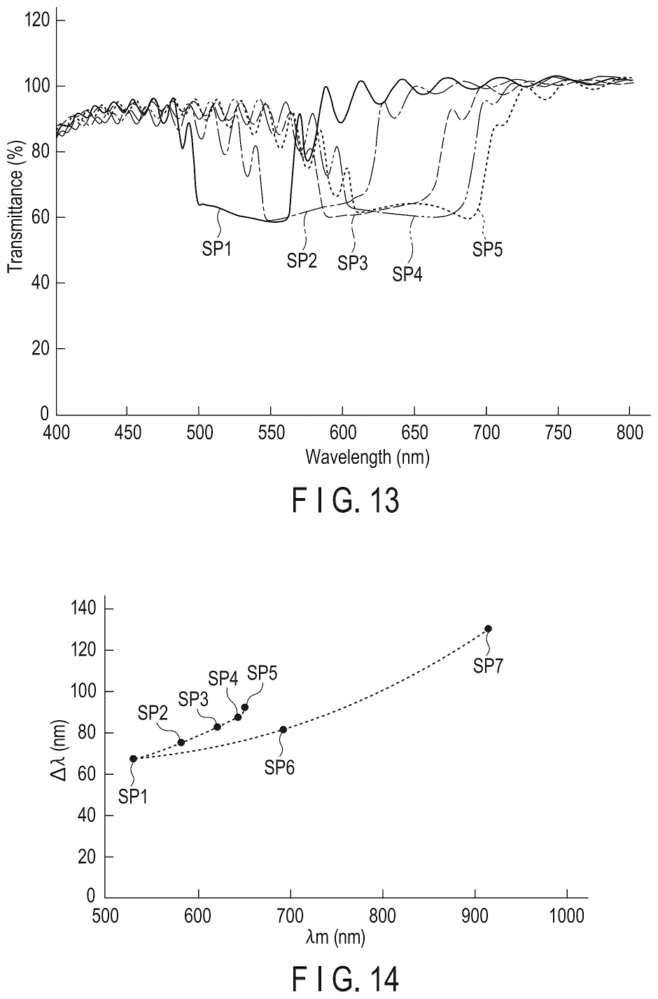

FIG. 13 is a diagram showing measurement results of the spectral transmission spectra of Samples 1 to 5.

The horizontal axis of the figure represents wavelength (nm) and the vertical axis of the figure represents transmittance (%).

SP1 in the figure represents the measurement result of Sample 1, SP2 in the figure represents the measurement result of Sample 2, SP3 in the FIG. represents the measurement result of Sample 3, SP4 in the figure represents the measurement result of Sample 4, and SP5 in the figure represents the measurement result of Sample 5.

From these measurement results, the selective reflection band Δλ and the center wavelength λm of the selective reflection band Δλ of each of Samples 1 to 5 were determined.

FIG. 14 is a diagram showing the relationship between the selective reflection band Δλ and the center wavelength λm of Samples 1 to 5.

The horizontal axis of the figure represents center wavelength λm (nm) and the vertical axis of the figure represents selective reflection band Δλ (nm).

These measurement results confirmed the following tendency: as the amount of added additive 4 increased, the selective reflection band Δλ became greater and the center wavelength λm of the selective reflection band Δλ also became longer.

SP6 and SP7 in the figure represent the measurement results of Samples 6 and 7, which were comparative examples. Sample 6 did not include the additive 4, like Sample 1, and comprised cholesteric liquid crystals of a helical pitch greater than the helical pitch of Sample 1. Sample 7 did not include the additive 4, like Sample 1, and comprised cholesteric liquid crystals of a helical pitch still greater than the helical pitch of Sample 6.

It was confirmed that in Samples 2 to 5, the selective reflection band Δλ could be enlarged more than in the comparative examples, in which the helical pitch was made greater to obtain the same center wavelength λm.

In addition, it was also confirmed that in Samples 2 to 5, the shift of the center wavelength λm to a long wavelength side can be reduced more than in the comparative examples, in which the helical pitch was made greater to obtain the same selective reflection band Δλ.

For Sample 2, the helical pitch P was determined on the basis of a cross-sectional photograph taken by an electron microscope and was 348 nm. In addition, the selective reflection band Δλ was determined on the basis of the measurement result of the above-described spectral transmission spectrum and was 74 nm. Accordingly, on the basis of the above-described equation (1), the refractive anisotropy Δn of the liquid crystal layer 3 was calculated at 0.213. This refractive anisotropy Δn was found to be greater than the refractive anisotropy Δn3 (=0.2) of the liquid crystal material applied to Example 1.

Similarly, for Sample 3, the helical pitch P was determined and was 378 nm. In addition, the selective reflection band Δλ was determined and was 83 nm. Accordingly, on the basis of the above-described equation (1), the refractive anisotropy Δn of the liquid crystal layer 3 was calculated at 0.220.

Similarly, for Sample 5, the helical pitch P was determined and was 388 nm. In addition, the selective reflection band Δλ was determined and was 92 nm. Accordingly, on the basis of the above-described equation (1), the refractive anisotropy Δn of the liquid crystal layer 3 was calculated at 0.237.

In this manner, for example, the helical pitch P of the cholesteric liquid crystals 311 is set to be greater than or equal to 300 nm but less than or equal to 700 nm. At this time, the refractive anisotropy Δn of the liquid crystal layer 3 is greater than or equal to 0.21 but less than or equal to 0.24, and as the additive 4, a material having refractive anisotropy Δn4 greater than 0.24 is applied.

In addition, from another point of view, the refractive anisotropy Δn3 of the cholesteric liquid crystals 311 is 0.2, and as the additive 4, a material having refractive anisotropy Δn4 greater than 0.2 is applied.

### Example 2

First, a liquid crystal material having refractive anisotropy Δn3 of 0.2 was applied as a material for forming the cholesteric liquid crystals 311, and the liquid crystal layer 3 was formed through the above-described steps ST1 to ST7.

Then, a liquid crystal solution with a concentration of 10 wt % was prepared by dissolving 4′-pentyl cyclohexane ester phenyl tolans (another name: ET50) as the additive 4 in cyclohexanone as a solvent. Then, through the above-described steps ST8 to ST10, the additive 4 was added to the liquid crystal layer 3.

In Example 2, too, the same advantages as those of Example 1 were obtained.

### Example 3

First, a liquid crystal material having refractive anisotropy Δn3 of 0.2 was applied as a material for forming the cholesteric liquid crystals 311, and the liquid crystal layer 3 was formed through the above-described steps ST1 to ST7.

Then, a liquid crystal solution with a concentration of 10 wt % was prepared by dissolving 4-methoxy-4′-propyl cyclohexane ester phenyl tolans (another name: ET301) as the additive 4 in cyclohexanone as a solvent. Then, through the above-described steps ST8 to ST10, the additive 4 was added to the liquid crystal layer 3.

In Example 3, too, the same advantages as those of Example 1 were obtained.

### Application Example

Next, a photovoltaic cell device 200 will be described as an application example of the liquid crystal optical element 100 of the present embodiment.

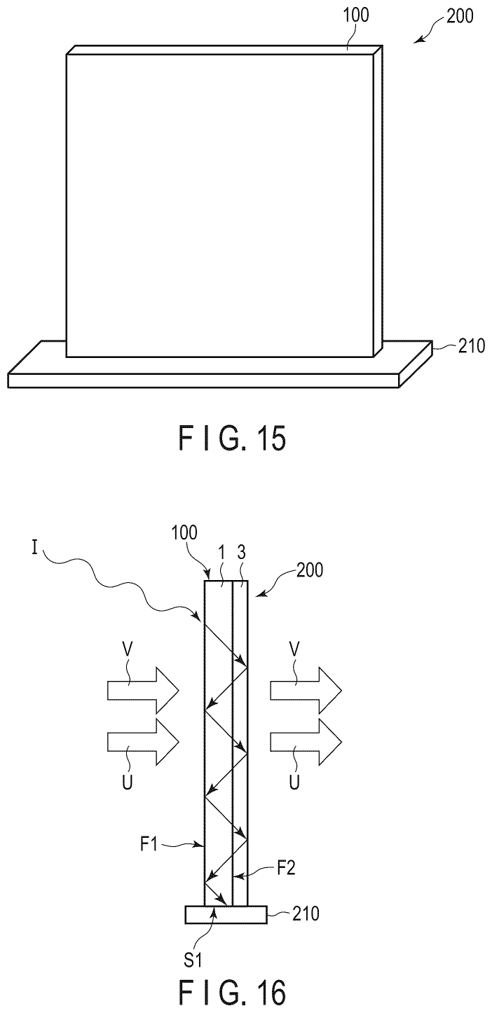

FIG. 15 is a diagram showing an example of the outside of the photovoltaic cell device 200.

The photovoltaic cell device 200 comprises the above-described liquid crystal optical element 100 and a power generation device 210. The power generation device 210 is provided along one side of the liquid crystal optical element 100. The one side of the liquid crystal optical element 100, which is opposed to the power generation device 210, is a side along the side surface S1 of the transparent substrate 1 shown in FIG. 1. In the photovoltaic cell device 200, the liquid crystal optical element 100 functions as a lightguide element which guides light of a predetermined wavelength to the power generation device 210.

The power generation device 210 comprises a plurality of photovoltaic cells. The photovoltaic cells receive light and convert the energy of received light into power. That is, the photovoltaic cells generate power from received light. The type of photovoltaic cells is not particularly limited. For example, the photovoltaic cells are silicon photovoltaic cells, compound photovoltaic cells, organic photovoltaic cells, perovskite photovoltaic cells, or quantum dot photovoltaic cells. The silicon photovoltaic cells include photovoltaic cells comprising amorphous silicon, photovoltaic cells comprising polycrystalline silicon, etc.

FIG. 16 is a diagram for explaining the operation of the photovoltaic cell device 200.

The first main surface F1 of the transparent substrate 1 faces outdoors. The liquid crystal layer 3 faces indoors. In FIG. 16, the illustration of an alignment film is omitted.

The liquid crystal layer 3 is, for example, configured to reflect first circularly polarized light of infrared rays I as shown in FIG. 1. The liquid crystal layer 3 may be configured to reflect each of first circularly polarized light and second circularly polarized light of infrared rays I.

Infrared rays I reflected by the liquid crystal layer 3 propagate through the liquid crystal optical element 100 toward the side surface S1. The power generation device 210 receives the infrared rays I transmitted through the side surface S1 and generates power.

Visible light V and ultraviolet rays U of solar light are transmitted through the liquid crystal optical element 100. In particular, a first component (blue component), a second component (green component), and a third component (red component), which are main components of visible light V, are transmitted through the liquid crystal optical element 100. Thus, the coloration of light transmitted through the photovoltaic cell device 200 can be suppressed. In addition, the decline of the transmittance of visible light V in the photovoltaic cell device 200 can be suppressed.

Furthermore, since the above-described liquid crystal optical element 100 is applied, the band which can be used for power generation can be enlarged and the power generation efficiency (conversion efficiency) can be improved.

As described above, the present embodiment can provide a liquid crystal optical element which can enlarge a reflection band.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A liquid crystal optical element comprising:
a transparent substrate comprising a first main surface and a second main surface opposed to the first main surface;
an alignment film disposed on the second main surface; and
a liquid crystal layer overlapping the alignment film and comprising a cholesteric liquid crystal and an additive exhibiting a liquid crystalline property,
refractive anisotropy of the additive being greater than refractive anisotropy of the liquid crystal layer.

2. A liquid crystal optical element comprising:
a transparent substrate comprising a first main surface and a second main surface opposed to the first main surface;
an alignment film disposed on the second main surface; and
a liquid crystal layer overlapping the alignment film and comprising a cholesteric liquid crystal and an additive exhibiting a liquid crystalline property,
refractive anisotropy of the additive being greater than refractive anisotropy of the cholesteric liquid crystal.

3. The liquid crystal optical element of claim 1, wherein the additive is formed of one of a nematic liquid crystal material and a smectic liquid crystal material.

4. The liquid crystal optical element of claim 3, wherein the additive is formed of one of a cyanobiphenyl-based material, an analog of the cyanobiphenyl-based material, a fluorinated biphenyl-based material, an analog of the fluorinated biphenyl-based material, another biphenyl-based material, an analog of the other biphenyl-based material, a phenyl ester-based material, a Schiff base-based material, a cyclohexane phenyl tolan-based material, a cyclohexane ester phenyl tolan-based material, an alkoxy cyclohexane ester phenyl tolan-based material, a fluoro cyclohexane ester phenyl tolan-based material, a tetracyclic ester tolan-based material, a phenyl tolan ester-based material, a cyano phenyl tolan ester-based material, a fluoro phenyl tolan ester-based material, and a bifluoro phenyl tolan ester-based material.

5. The liquid crystal optical element of claim 1, wherein a helical pitch of the cholesteric liquid crystal is greater than or equal to 300 nm but less than or equal to 700 nm.

6. The liquid crystal optical element of claim 1, wherein the refractive anisotropy of the liquid crystal layer is greater than or equal to 0.21 but less than or equal to 0.24, and
the refractive anisotropy of the additive is greater than 0.24.

7. The liquid crystal optical element of claim 2, wherein the refractive anisotropy of the cholesteric liquid crystal is 0.2, and
the refractive anisotropy of the additive is greater than 0.2.

8. The liquid crystal optical element of claim 2, wherein the additive is formed of one of a nematic liquid crystal material and a smectic liquid crystal material.

9. The liquid crystal optical element of claim 8, wherein the additive is formed of one of a cyanobiphenyl-based material, an analog of the cyanobiphenyl-based material, a fluorinated biphenyl-based material, an analog of the fluorinated biphenyl-based material, another biphenyl-based material, an analog of the other biphenyl-based material, a phenyl ester-based material, a Schiff base-based material, a cyclohexane phenyl tolan-based material, a cyclohexane ester phenyl tolan-based material, an alkoxy cyclohexane ester phenyl tolan-based material, a fluoro cyclohexane ester phenyl tolan-based material, a tetracyclic ester tolan-based material, a phenyl tolan ester-based material, a cyano phenyl tolan ester-based material, a fluoro phenyl tolan ester-based material, and a bifluoro phenyl tolan ester-based material.

10. The liquid crystal optical element of claim 2, wherein a helical pitch of the cholesteric liquid crystal is greater than or equal to 300 nm but less than or equal to 700 nm.
